(19) United States
(12) Patent Application Publication
(10) Pub. No.: US 2026/0212932 A1
(43) Pub. Date: Jul. 23, 2026

(54) SEMICONDUCTOR MEMORY DEVICE

(71) Applicant: Kioxia Corporation, Tokyo (JP)

(72) Inventors: Ryuta WASEDA, Yokohama (JP); Xiaoqing WANG, Fujisawa (JP)

(73) Assignee: Kioxia Corporation, Tokyo (JP)

(21) Appl. No.: 19/314,593

(22) Filed: Aug. 29, 2025

(30) Foreign Application Priority Data
Jan. 22, 2025 (JP) 2025-009249

(51) Int. Cl. G11C 16/10; G11C 16/04; G11C 16/26; G11C 16/34

(52) U.S. Cl. CPC G11C 16/105; G11C 16/0483; G11C 16/26; G11C 16/3459

(57) ABSTRACT

According to one embodiment, a semiconductor memory device includes a control circuit, a first word line, and a memory array including a first memory cell configured to store n bits, in which the control circuit is configured to execute first and second write operations in response to first and second write instructions from an external memory controller, execute first and second read operations in response to first and second read instructions, and control a threshold voltage of the first memory cell to any of 2ⁿ distributions including a first distribution and a second distribution or 2ⁿ distributions including a third distribution and a fourth distribution arranged in an order of increasing voltage by executing the first or second write operation, and at least a part of the third distribution exists between the first distribution and the second distribution.

### CROSS-REFERENCE TO RELATED APPLICATION

This application is based upon and claims the benefit of priority from Japanese Patent Application No. 2025-009249, filed January 22, 2025, the entire contents of which are incorporated herein by reference.

### FIELD

Embodiments described herein relate generally to a semiconductor memory device.

### BACKGROUND

A NAND flash memory is known as a semiconductor memory device, and a memory system including the NAND flash memory and a memory controller that controls the NAND flash memory is known.

### DESCRIPTION OF THE DRAWINGS

FIG. 1 is a block diagram illustrating a configuration of a memory system according to an embodiment.

FIG. 2 is a block diagram illustrating a configuration of a semiconductor memory device according to the embodiment.

FIG. 3 is a diagram showing a circuit configuration of a memory cell array of the semiconductor memory device according to the embodiment.

FIG. 4 is a cross-sectional view of the semiconductor memory device according to the embodiment.

FIG. 5 is a diagram showing an equivalent circuit of adjacent strings in the semiconductor memory device according to the embodiment.

FIG. 6 is a diagram showing a threshold voltage distribution of a memory cell according to the embodiment.

FIG. 7 is a diagram illustrating the threshold voltage distribution, and a normal mode and a stealth mode of the memory cell according to the embodiment.

FIG. 8 is a diagram showing a circuit configuration of a block in the semiconductor memory device according to the embodiment.

FIG. 9 is a diagram showing a circuit configuration of a block in the semiconductor memory device according to the embodiment.

FIG. 10 is a diagram showing a circuit configuration of a block in the semiconductor memory device according to the embodiment.

### DETAILED DESCRIPTION

Embodiments provide a semiconductor memory device capable of increasing the security of data stored in the semiconductor memory device.

In general, according to one embodiment, a semiconductor memory device includes a control circuit, a first word line, and a memory array including a first memory cell connected to the first word line and configured to store n bits (where n is an integer equal to or greater than one), in which the control circuit is configured to execute a first write operation in response to a first write instruction from an external memory controller, execute a second write operation in response to a second write instruction from the external memory controller, execute a first read operation in response to a first read instruction from the memory controller, and execute a second read operation in response to a second read instruction from the memory controller, control a threshold voltage of the first memory cell to any of 2ⁿ distributions including a first distribution and a second distribution arranged in an order of increasing voltage by executing the first write operation, determine whether the threshold voltage of the first memory cell is the first distribution or the second distribution, on the basis of a first voltage by executing the first read operation, control the threshold voltage of the first memory cell to any of 2ⁿ distributions including a third distribution and a fourth distribution arranged in an order of increasing voltage by executing the second write operation, and determine whether the threshold voltage of the first memory cell is the third distribution or the fourth distribution, on the basis of a second voltage higher than the first voltage by executing the second read operation, and at least a part of the third distribution exists between the first distribution and the second distribution.

Hereinafter, a semiconductor memory device according to the present embodiment will be specifically described with reference to the drawings. In the following description, elements having substantially the same functions and configurations are given the same reference numerals, and will be described repeatedly only when necessary. Each embodiment shown below is an example of a device and a method for embodying the technical idea of the embodiment. The technical idea of the embodiment is not limited to the materials, shapes, structures, dispositions, and the like of the components described below. The technical idea of the embodiment may be changed in various ways within the scope of the claims.

### 1. First Embodiment

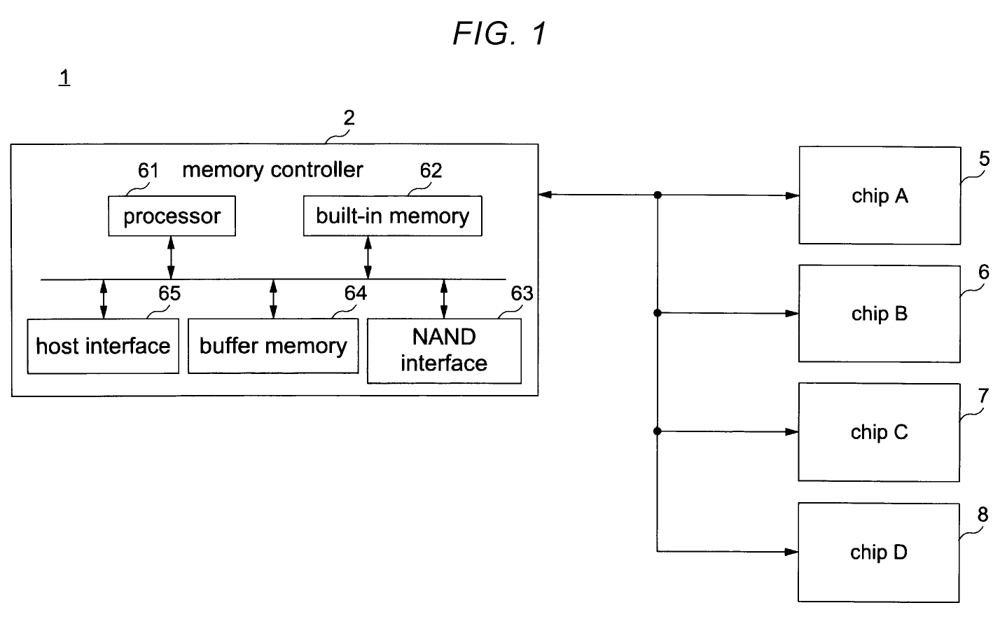

A semiconductor memory device according to a first embodiment will be described with reference to FIGS. 1 to 7.

### 1-1. Overall Configuration of Memory System

FIG. 1 is a block diagram illustrating a configuration of a memory system according to an embodiment. As shown in FIG. 1, a memory system 1 according to the first embodiment includes a memory controller 2 and semiconductor memory devices 5 to 8 (chips A to D). The memory controller 2 is connected to the semiconductor memory devices 5 to 8 by a bus. A non-volatile memory such as a NAND flash memory is used as the semiconductor memory devices 5 to 8. The memory controller 2 controls the operations of the semiconductor memory devices 5 to 8.

The memory controller 2 communicates with, for example, an external host computer (not shown). The memory controller 2 instructs the semiconductor memory devices 5 to 8 to execute a write operation and a read operation in response to a write request (or command) and a read request (or command) received from the host computer. When the memory controller 2 receives the write command, the memory controller 2 gives a write instruction to the semiconductor memory devices 5 to 8, so that the write operation is executed. When the memory controller 2 receives the read command, the memory controller 2 gives a read instruction to the semiconductor memory devices 5 to 8, so that the read operation is executed. When the read operation is executed, the memory controller 2 transmits data stored in the semiconductor memory devices 5 to 8 to the host computer.

The semiconductor memory devices 5 to 8 include a plurality of memory cells and store data in a non-volatile manner. The semiconductor memory devices 5 to 8 are semiconductor chips that can be identified as individuals. For example, the semiconductor memory devices 5 to 8 are identified by individual chip enable signals. Alternatively, the semiconductor memory devices 5 to 8 are identified in such a manner that individual chip addresses are assigned to the respective semiconductor memory devices in advance. Therefore, the semiconductor memory devices 5 to 8 are controlled independently under the instruction of the memory controller 2.

The memory controller 2 transmits various signals to the semiconductor memory devices 5 to 8 via the bus and receives various signals from the semiconductor memory devices 5 to 8. The bus includes a plurality of signal lines and transmits and receives signals according to an instruction transmitted from the memory controller 2. The signals transmitted and received via the bus are, for example, a chip enable signal, a command latch enable signal, an address latch enable signal, a write enable signal, a read enable signal, an output instruction signal, a write protect signal, a data signal (including a data strobe signal), and a ready-busy signal.

As shown in FIG. 1, the memory controller 2 includes a processor 61 (processor), a built-in memory 62 (built-in memory), a NAND interface circuit 63 (NAND interface), a buffer memory 64 (buffer memory), and a host interface circuit 65 (host interface).

The processor 61 is, for example, a central processing unit (CPU) and controls the operation of the entire memory controller 2. The processor 61 transmits a write instruction to the semiconductor memory devices 5 to 8 via the NAND interface circuit 63 according to the write command of data received from the external host computer, for example. This function is a function common to the read operation, an erase operation, and the like, as well as the write operation. The host computer may be referred to as a host or a host apparatus.

The built-in memory 62 is, for example, a semiconductor memory such as a random access memory (RAM) or a dynamic RAM (DRAM), and is used as a work area of the processor 61. The built-in memory 62 stores firmware for managing the semiconductor memory devices 5 to 8, various management tables, and the like.

The NAND interface circuit 63 is connected to the semiconductor memory devices 5 to 8 via the above-described bus, and executes communication with the semiconductor memory devices 5 to 8. The NAND interface circuit 63 transmits an operation instruction, an address, and write data to the semiconductor memory devices 5 to 8 according to an instruction of the processor 61. The NAND interface circuit 63 receives status and read data from the semiconductor memory devices 5 to 8.

The buffer memory 64 temporarily stores data and the like received from the semiconductor memory devices 5 to 8 and the outside by the memory controller 2.

The host interface circuit 65 is connected to the external host computer and executes communication with the host computer. The host interface circuit 65 transfers, for example, the command received from the host computer to the processor 61 and the buffer memory 64.

### 1-2. Configuration of Semiconductor Memory Device

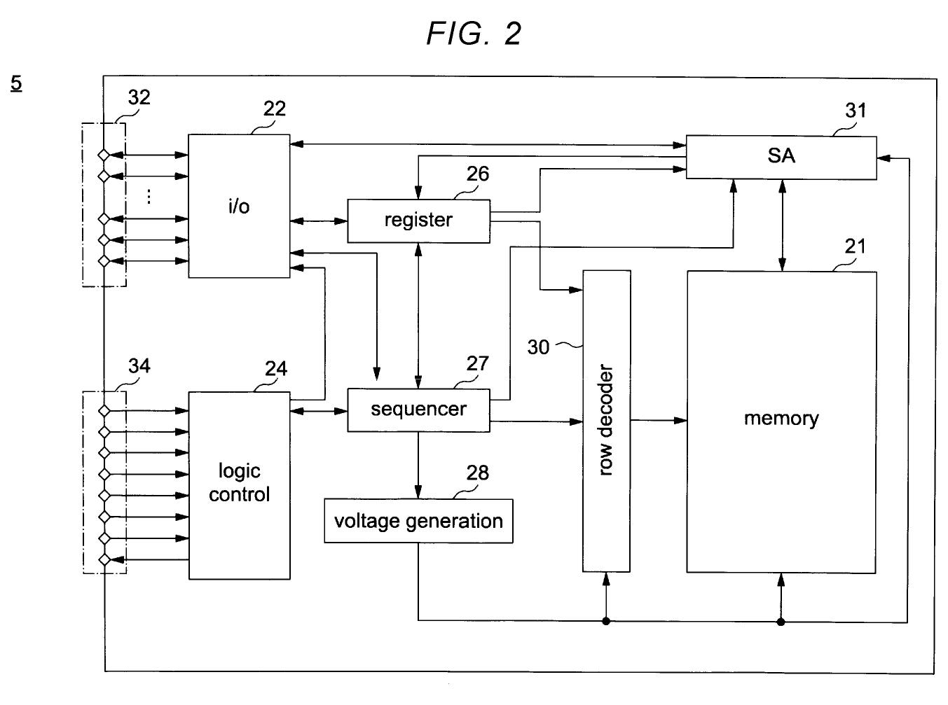

A configuration example of the semiconductor memory device according to the first embodiment will be described with reference to FIG. 2. The semiconductor memory devices 5 to 8 have, for example, the same configuration. For this reason, in the following description, the configuration of the semiconductor memory device 5 among the semiconductor memory devices 5 to 8 is described, and the configurations of the semiconductor memory devices 6 to 8 are not described.

As shown in FIG. 2, the semiconductor memory device 5 includes a memory cell array 21 (memory), an input/output circuit 22 (i/o), a logic control circuit 24 (logic control), a register 26 (register), a sequencer 27 (sequencer), a voltage generation circuit 28 (voltage generation), a row decoder 30 (row decoder), a sense amplifier 31 (SA), an input/output pad group 32, and a logic control pad group 34.

Though details will be described below, the memory cell array 21 includes a plurality of non-volatile memory cells (memory cell transistors MT described below) associated with word lines and bit lines.

The input/output circuit 22 transmits and receives a data signal to and from the memory controller 2. The input/output circuit 22 transfers a command and an address in the data signal to the register 26. The input/output circuit 22 transmits and receives the write data and the read data to and from the sense amplifier 31.

The logic control circuit 24 receives, for example, the chip enable signal, the command latch enable signal, the address latch enable signal, the write enable signal, the read enable signal, the output instruction signal, and the write protect signal from the memory controller 2. The logic control circuit 24 transmits the ready-busy signal to the memory controller 2 to notify the memory controller 2 of the state of the semiconductor memory device 5.

The register 26 stores the command and the address. The register 26 transfers the address to the row decoder 30 and the sense amplifier 31, and transfers the command to the sequencer 27. The sequencer 27 receives the command and controls the entire semiconductor memory device 5 according to a sequence based on the received command. The sequencer 27 may be referred to as a "control circuit".

Though the details will be described below, in the present embodiment, the sequencer 27 executes a write operation and a read operation in a "normal mode" or a write operation and a read operation in a "stealth mode" in the write operation and the read operation. Data written to a memory cell by the write operation in the stealth mode can be correctly read only by the read operation in the stealth mode, and cannot be correctly read by the read operation in the normal mode. Though the details will be described below, even in the same block, the normal mode and the stealth mode may be separated in units of pages. In this case, identification information with which an address corresponding to a page in the normal mode from an address corresponding to a page in the stealth mode can be distinguished is stored in the memory cell array 21. An address in the memory cell array 21 in which the identification information is stored is managed by the memory controller 2. The identification information may be stored in a read only memory (ROM) (not shown) provided in the memory controller 2. Even in this case, as in the above-described case, an address in the ROM in which the identification information is stored is managed by the memory controller 2.

The voltage generation circuit 28 generates a voltage required for the write operation, the read operation, the erase operation, and the like of data on the basis of an instruction from the sequencer 27. The voltage generation circuit 28 includes a plurality of drivers, and supplies the generated voltage to the row decoder 30 and the sense amplifier 31 under the control of the sequencer 27. The voltage generation circuit 28 supplies the generated voltage to the corresponding row decoder 30 on the basis of a row address included in an instructed address, for example.

The row decoder 30 selects a memory cell corresponding to the row address included in the instructed address under the control of the sequencer 27. The voltage supplied from the voltage generation circuit 28 via the row decoder 30 is applied to the memory cell of the selected row.

The sense amplifier 31 detects read data read from the memory cell to the bit line during the read operation of data and transfers the detected read data to the input/output circuit 22. The sense amplifier 31 transfers data written via the bit line to the memory cell during the write operation of data. The sense amplifier 31 transfers data corresponding to the instructed address to the input/output circuit 22 under the control of the sequencer 27.

The input/output pad group 32 transfers the data signal received from the memory controller 2 to the input/output circuit 22. The input/output pad group 32 transfers the data signal received from the input/output circuit 22 to the memory controller 2. The logic control pad group 34 transfers various signals received from the memory controller 2 to the logic control circuit 24.

### 1-3. Configuration of Memory Cell Array

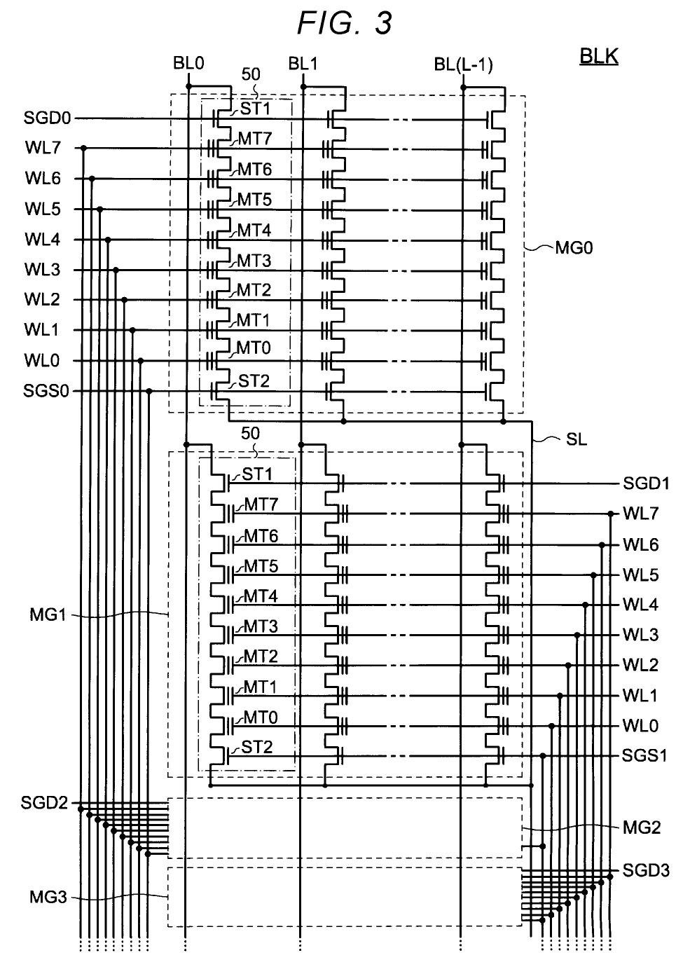

A circuit configuration of the memory cell array 21 will be described with reference to FIG. 3. FIG. 3 is an equivalent circuit diagram of a block BLK. As shown in the drawing, the block BLK includes a plurality of memory groups MG (MG0, MG1, MG2, ...). The memory group MG includes a plurality of strings 50.

In the present embodiment, each of the strings 50 includes eight memory cell transistors MT (MT0 to MT7) and two select transistors ST (ST1 and ST2). The eight memory cell transistors MT are connected in series between a source of the select transistor ST1 and a drain of the select transistor ST2.

In the present embodiment, while a configuration in which the number of memory cell transistors MT provided in the string 50 is eight was described as an example, the present disclosure is not limited to this configuration. For example, the number of memory cell transistors MT provided in each string 50 may be equal to or smaller than seven or may be equal to or greater than nine. The number of select transistors ST is not limited to the above-described configuration.

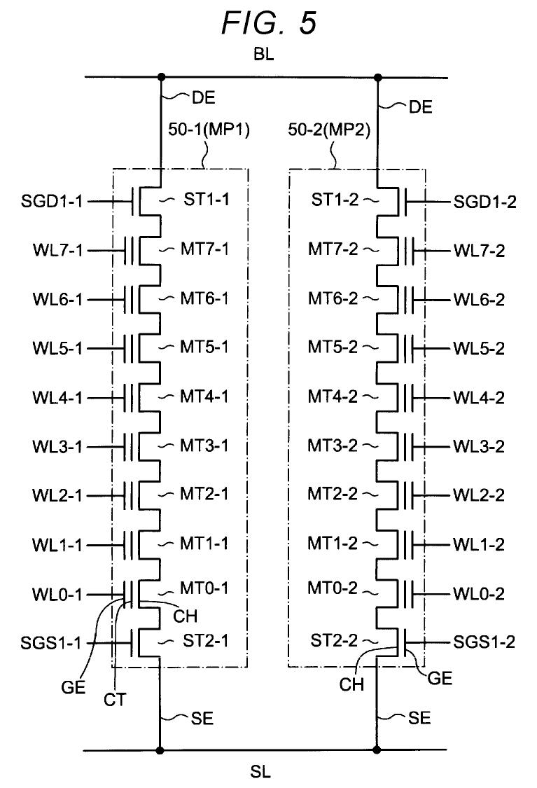

Though the details will be described below, each of the memory cell transistors MT includes a gate electrode GE that controls an on state and an off state of the transistor, and a charge storage layer CT that stores electric charge injected by a write operation (see FIG. 5). The memory cell transistor MT has a threshold voltage according to an amount of electric charge stored in the charge storage layer CT, and is brought into the on state when a voltage equal to or higher than the threshold voltage is applied to the gate electrode GE. When the write operation for the memory cell transistor MT, that is, the injection of electrons into the charge storage layer CT of the memory cell transistor MT is performed, the threshold voltage of the memory cell transistor MT changes. When the memory cell is an N-type transistor, the threshold voltage of the memory cell transistor MT in a state in which the electrons are injected into the charge storage layer CT is higher than the threshold voltage of the memory cell transistor MT in a state in which the electrons are not injected into the charge storage layer CT. The memory cell transistor MT stores data in a non-volatile manner according to change in threshold voltage with the injection of the electrons into the charge storage layer CT.

As shown in FIG. 3, a gate of the select transistor ST1 in the memory group MG is connected to a select gate line SGD (SGD0, SGD1, ...). A gate of the select transistor ST2 is connected to a select gate line SGS (SGS0, SGS1, ...). The select gate lines SGD and SGS are controlled independently by the row decoder 30. In the present embodiment, while a configuration in which the numbers of select gate lines SGD and SGS are both one was described as an example, the present embodiment is not limited to this configuration. The numbers of select gate lines SGD and SGS may be both equal to or greater than two. That is, two or more select transistors ST1 and ST2 may be provided.

The gate electrodes GE of the memory cell transistors MT0 to MT7 that are provided in the same memory group MG and belong to different bit lines BL are connected to word lines WL0 to WL7, respectively. The word lines WL (WL0 to WL7) are independently controlled by the row decoder 30.

The block BLK is, for example, an erase unit of data. That is, data stored in the memory cell transistors MT provided in the same block BLK is collectively erased. When the memory cell is an N-type transistor, the threshold voltage of the memory cell transistor MT in a state in which data is erased (erased state) is lower than the threshold voltage of the memory cell transistor MT in a state in which data is written (written state).

In the memory cell array 21, drains of the select transistors ST1 of the plurality of strings 50 provided in the same column are connected to a common bit line BL (BL0 to BL(L-1) (where L is a natural number equal to or greater than three)). In the memory cell array 21, sources of the plurality of select transistors ST2 are commonly connected to a source line SL.

### 1-4. Cross-Sectional Structure of Memory Cell Array

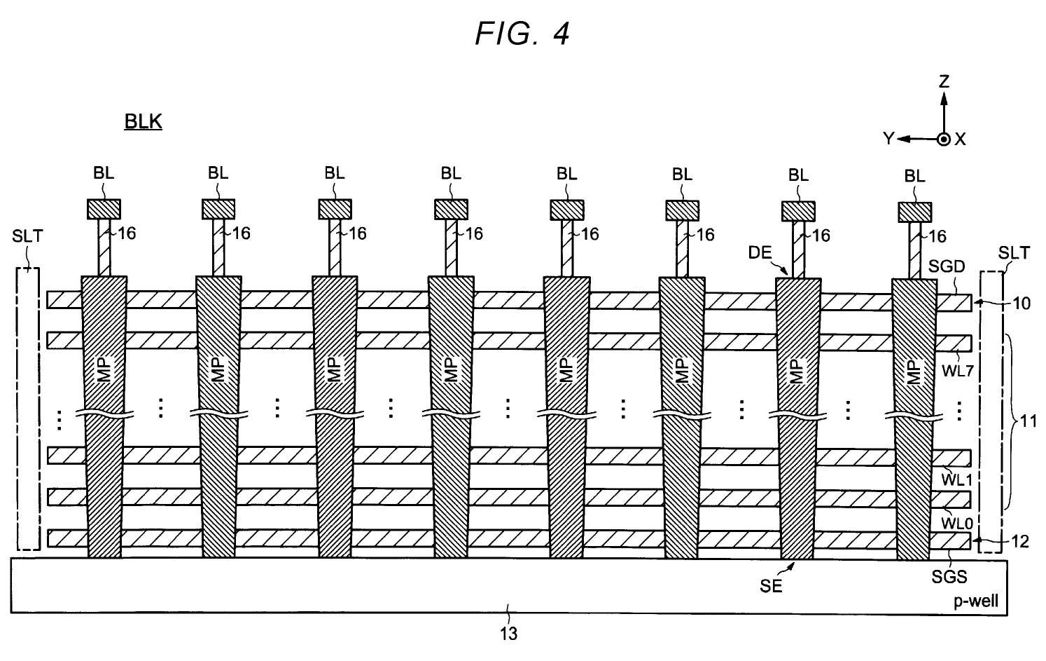

A certain cross-sectional structure of the memory cell array 21 will be described with reference to FIG. 4. The memory cell array 21 includes wiring layers 10 to 12, a semiconductor substrate 13, contact plugs 16, memory pillars MP, and bit lines BL.

As shown in FIG. 4, the wiring layer 12 serving as the select gate line SGS is provided above the semiconductor substrate 13. The wiring layer 11 having eight wiring layers serving as the word lines WL0 to WL7 is provided above the wiring layer 12. The eight wiring layers 11 are stacked along the Z direction. The wiring layer 10 serving as the select gate line SGD is provided above the wiring layer 11.

Each of the memory pillars MP is longitudinal in the Z direction and passes through the wiring layers 10 to 12 to connect the semiconductor substrate 13 and the contact plug 16. The memory pillar MP includes a semiconductor layer. The memory cell transistor MT is formed in a region where the memory pillar MP and the word line WL face each other. Similarly, the select transistor ST1 is formed in a region where the memory pillar MP and the select gate line SGD face each other. The select transistor ST2 is formed in a region where the memory pillar MP and the select gate line SGS face each other. As a semiconductor in the memory pillar MP, monocrystalline or polycrystalline silicon is used. It should be noted that a material other than silicon may be used as the semiconductor layer. The semiconductor layer may be amorphous or may be a mixed layer of amorphous and polycrystalline.

In the Y direction, the memory pillar MP is sandwiched by each of the wiring layer 10 (select gate line SGD), the wiring layer 11 (word line WL), and the wiring layer 12 (select gate line SGS). The memory pillar MP is also sandwiched by the wiring layers in the X direction. That is, the periphery of the memory pillar MP is surrounded by the wiring layer in the XY plane. It should be noted that the present embodiment is not limited to this configuration, and it should suffice that the wiring layers 10 to 12 face the memory pillar MP.

A region of the semiconductor substrate 13 connected to the memory pillar MP may be referred to as a "source electrode SE". A region of the contact plug 16 connected to the memory pillar MP may be referred to as a "drain electrode DE".

A slit SLT is provided between the blocks BLK adjacent to each other in the Y direction. An insulating layer is provided in the slit SLT. It should be noted that a contact plug or the like for supplying (applying) a voltage to a region provided in the semiconductor substrate 13 may be provided in the slit SLT. For example, a contact plug or a groove-shaped conductor for connecting the source of the select transistor ST2 to the source line may be provided in the slit SLT.

The bit line BL is provided on the memory pillar MP. The contact plug 16 for connecting the memory pillar MP and the bit line BL is provided between the memory pillar MP and the bit line BL.

### 1-5. Equivalent Circuit

FIG. 5 is a diagram showing an equivalent circuit of adjacent strings in the semiconductor memory device according to the embodiment. As shown in FIG. 5, one string 50 is provided in one memory pillar MP. FIG. 5 shows two memory pillars MP1 and MP2. The memory cell transistors MT and the select transistors ST that belong to the memory pillar MP1 are given "-1" after the reference numerals, and the memory cell transistors MT and the select transistors ST that belong to the memory pillar MP2 are given "-2" after the reference numerals. In the following description, when there is no need for particular distinction between the memory cell transistors MT and the select transistors ST that belong to the memory pillars MP1 and MP2, the memory cell transistors MT and the select transistors ST are described without "-1" and "-2".

The string 50 is provided between the bit line BL and the source line SL, and has the select transistor ST1, i memory cell transistors MT (where i is an integer equal to or greater than two, and is eight in the present embodiment), and the select transistor ST2 connected in series. The string 50 is connected to the source line SL via the source electrode SE and is connected to the bit line BL via the drain electrode DE. In the present embodiment, since i is 8, the memory cell transistors MT0 to MT7 are provided. The i memory cell transistors MT are connected in series between the select transistor ST1 and the select transistor ST2. The i memory cell transistors MT are disposed along the Z direction.

The source line SL is provided on a main surface of the semiconductor substrate 13 (see FIG. 4). The source line SL may have a configuration in which a conductive layer with no pattern extends to the region of the memory cell array 21 or may have a configuration in which a conductive layer with a linear pattern extends to the region. In other words, the source line SL extends in the X direction and the Y direction. The source line SL may be formed of a conductive semiconductor having conductivity as a part of the semiconductor substrate 13 or may be formed of a metal material formed on the semiconductor substrate 13.

Each of the strings 50-1 and 50-2 is connected to the common bit line BL and the common source line SL. The word lines WL0-1 to WL7-1 are controlled independently of the word lines WL0-2 to WL7-2. The select gate lines SGD1-1 and SGS1-1 are controlled independently of the select gate lines SGD1-2 and SGS1-2.

In FIG. 5, the memory cell transistor MT includes a channel portion CH, the charge storage layer CT, and the gate electrode GE. The channel portion CH is a portion that serves as a channel of the memory cell transistor MT. The charge storage layer CT stores electric charge injected by the write operation. The threshold voltage of the memory cell transistor MT fluctuates according to an amount of electric charge stored in the charge storage layer CT. The gate electrode GE is connected to the word line WL. The channel portion CH, the charge storage layer CT, and the gate electrode GE are insulated from each other by an insulating layer.

The charge storage layer CT may be, for example, a floating gate such as a metal layer or a charge trap layer such as a silicon nitride layer. The memory cell transistor MT may be a memory cell including a ferroelectric insulating layer. In this case, a ferroelectric insulating film is provided between the channel portion CH and the gate electrode GE, and the threshold voltage of the memory cell transistor MT changes with change in dielectric constant.

The select transistor ST includes the channel portion CH and the gate electrode GE. No charge storage layer CT is provided in the select transistor ST. The gate electrode GE of the select transistor ST1 is connected to the select gate line SGD1. The gate electrode GE of the select transistor ST2 is connected to the select gate line SGS1. Unlike the example in FIG. 5, the charge storage layer CT may be provided in the select transistor ST.

### 1-6. Threshold Voltage Distribution of Memory Cell

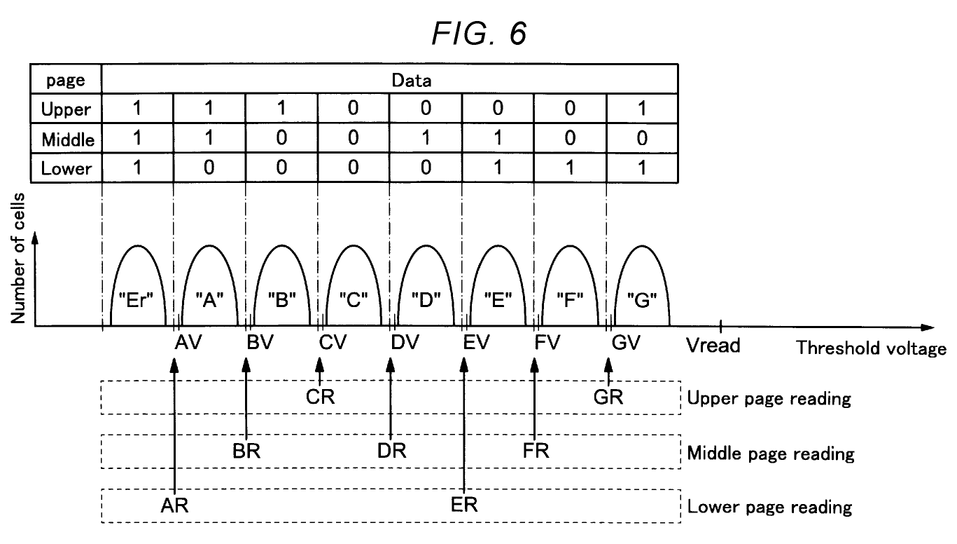

FIG. 6 is a diagram showing a threshold voltage distribution of a memory cell that is used as the memory cell according to the embodiment. FIG. 6 illustrates a Triple-Level Cell (TLC) as an example of a threshold voltage distribution. It should be noted that, in the memory system 1, a Hexa-Level Cell (HLC), a Penta-Level Cell (PLC), a Quad-Level Cell (QLC), a Multi-Level Cell (MLC), or a Single-Level Cell (SLC) may be used. One memory cell is configured to store n bits (where n is an integer equal to or greater than one), and is an SLC when n is 1, an MLC when n is 2, a TLC when n is 3, a QLC when n is 4, a PLC when n is 5, and an HLC when n is 6. In addition, in the threshold voltage distribution of each level cell, 2ⁿ distributions are formed. Since the memory cell shown in FIG. 6 is TLC (n = 3), eight threshold voltage distributions exist as shown in FIG. 6.

FIG. 6 shows an example of a threshold voltage distribution, allocation of data, and a read voltage of each memory cell. A vertical axis of the threshold voltage distribution corresponds to the number of memory cells (Number of cells), and a horizontal axis corresponds to a threshold voltage Vth (Threshold voltage) of the memory cell.

In the TLC type memory cell, each of the eight threshold voltage distributions may be referred to as a write level. The write levels are referred to as an "Er" level, an "A" level, a "B" level, a "C" level, a "D" level, an "E" level, an "F" level, and a "G" level in an order of increasing threshold voltage. The "Er" level indicates an erased state. The memory controller 2 transitions the memory cell at the "Er" level to any state of the "A" level to the "G" level by repeating a program operation and a verify operation. The program operation is an operation to change the threshold voltage of the memory cell to a high voltage side (e.g., increase the threshold voltage of the memory cell). The verify operation is an operation to determine whether the threshold voltage of the memory cell that was changed by the program operation reaches any state of the "A" level to the "G" level.

Among these threshold voltage distributions, two adjacent distributions may be referred to as a "first distribution" and a "second distribution" in an order of increasing threshold voltage. The same also applies to the SLC type, the MLC type, and the QLC type. For example, different three-bit data as described below is assigned to these write levels. The three-bit data is referred to as a lower bit (Lower), a middle bit (Middle), and an upper bit (Upper).

In the present embodiment, the write level and the three-bit data correspond to each other as follows.

"Er" level: "111" data

"A" level: "110" data

"B" level: "100" data

"C" level: "000" data

"D" level: "010" data

"E" level: "011" data

"F" level: "001" data

"G" level: "101" data

The above-described three-bit data is written in the order of Upper, Middle, and Lower.

A set of Lower bits that are stored in the memory cells connected to the same word line is referred to as a Lower page, a set of Middle bits is referred to as a Middle page, and a set of Upper bits is referred to as an Upper page. For example, the write operation and the read operation of data are performed in units of pages described above.

A verify voltage that is used in the write operation is set between adjacent threshold voltage distributions. Specifically, verify voltages AV, BV, CV, DV, EV, FV, and GV are set to correspond to the "A" level, the "B" level, the "C" level, the "D" level, the "E" level, the "F" level, and the "G" level, respectively.

For example, the verify voltage AV is set between the maximum threshold voltage at the "Er" level and the minimum threshold voltage at the "A" level. When the verify voltage AV is applied to the memory cell transistor, the memory cell transistor in which the threshold voltage is included in the "Er" level is brought into the on state, and the memory cell transistor in which the threshold voltage is included in the threshold voltage distribution equal to or higher than the "A" level is brought into the off state.

The other verify voltages BV, CV, DV, EV, FV, and GV are also set similarly to the verify voltage AV. The verify voltage BV is set between the "A" level and the "B" level. The verify voltage CV is set between the "B" level and the "C" level. The verify voltage DV is set between the "C" level and the "D" level. The verify voltage EV is set between the "D" level and the "E" level. The verify voltage FV is set between the "E" level and the "F" level. The verify voltage GV is set between an "F" level and a "G" level.

A read voltage that is used in the read operation is set between adjacent threshold voltage distributions. For example, a read voltage AR for determining whether the threshold voltage of the memory cell is included in the "Er" level or is included in the "A" level or higher is set between a maximum threshold voltage at the "Er" level and a minimum threshold voltage at the "A" level. The read voltage AR is lower than the verify voltage AV. The read voltage AR may be the same as the verify voltage AV.

Other read voltages BR, CR, DR, ER, FR, and GR are also set between adjacent levels similarly to the read voltage AR. For example, the read voltage BR is set between the "A" level and the "B" level. The read voltage CR is set between the "B" level and the "C" level. The read voltage DR is set between the "C" level and the "D" level. The read voltage ER is set between the "D" level and the "E" level. The read voltage FR is set between the "E" level and the "F" level. The read voltage GR is set between the "F" level and the "G" level.

During the read operation, a read voltage Vread for forcibly bringing the memory cell transistor MT corresponding to an unselected word line WL (a word line WL that is not a target of the read operation) into the on state is supplied to the unselected word line WL. The voltage Vread is set to a voltage value higher than a maximum threshold voltage of the highest threshold voltage distribution (for example, the "G" level). The memory cell transistor MT to the gate of which the voltage Vread is applied is brought into the on state regardless of data to be stored.

When the allocation of data described above is applied, one-page data of the lower bits (data of the lower page) is determined on the basis of the read result obtained using the read voltages AR and ER in the read operation. One-page data of the middle bits (data of the middle page) is determined on the basis of the read result using the read voltages BR, DR, and FR. One-page data of the upper bits (data of the upper page) is determined on the basis of the read result using the read voltages CR and GR. As described above, since data of the Lower page, data of the Middle page, and data of the Upper page are determined by two read operations, three read operations, and two read operations, respectively, the allocation of data is referred to as a "2-3-2 code". The allocation of data of each memory cell is not limited to the example of "2-3-2 code" shown in FIG. 6. For example, the allocation of data may be a "1-3-3 code". When the memory cell is QLC (n = 4), there are 16 threshold voltage distributions, and as the allocation of data, for example, there are "1-2-4-8 code" and "3-4-4-4 code".

### 1-7. Description of Normal Mode and Stealth Mode

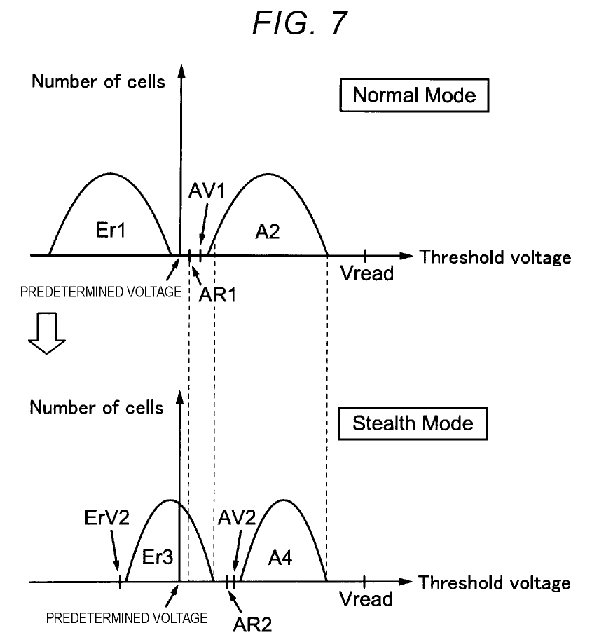

The threshold voltage distribution and the read operation in each of the normal mode and the stealth mode will be described with reference to FIG. 7. In FIG. 7, for convenience of description, the SLC type is described. Therefore, FIG. 7 shows two write levels of the "Er" level and the "A" level. A threshold voltage distribution on an upper side in FIG. 7 is the normal mode, and a threshold voltage distribution on a lower side is the stealth mode. In the following description, the "Er" level in the normal mode is referred to as a first distribution Er1, and the "A" level in the normal mode is referred to as a second distribution A2. On the other hand, the "Er" level in the stealth mode is referred to as a third distribution Er3, and the "A" level in the stealth mode is referred to as a fourth distribution A4.

By executing the write operation in the normal mode for the memory cell, the threshold voltage of the memory cell is controlled to the first distribution Er1 or the second distribution A2. For example, the threshold voltage of the memory cell is controlled to fall within the first distribution Er1 or the second distribution A2. On the other hand, by executing the write operation in the stealth mode for the memory cell, the threshold voltage of the memory cell is controlled to the third distribution Er3 or the fourth distribution A4. For example, the threshold voltage of the memory cell is controlled to fall within the third distribution Er3 or the fourth distribution A4.

When the threshold voltage of the memory cell is controlled to the second distribution A2 in the normal mode, the program operation and the verify operation are repeated until the threshold voltage reaches a verify voltage AV1. Similarly, when the threshold voltage of the memory cell is controlled to the fourth distribution A4 in the stealth mode, the program operation and the verify operation are repeated until the threshold voltage reaches a verify voltage AV2. As shown in FIG. 7, the verify voltage AV2 is higher than the verify voltage AV1. The threshold voltage distribution of the memory cell in an initial state is the first distribution Er1 regardless of the mode. For this reason, when the threshold voltage of the memory cell is controlled to the third distribution Er3 in the stealth mode, the program operation and the verify operation are repeated until the threshold voltage reaches a verify voltage ErV2.

By executing the read operation in the normal mode for the memory cell, determination of whether the threshold voltage of the memory cell is the first distribution Er1 or the second distribution A2 is performed on the basis of a read voltage AR1 in the normal mode. By executing the read operation in the stealth mode for the memory cell, determination of whether the threshold voltage of the memory cell is the third distribution Er3 or the fourth distribution A4 is performed on the basis of a read voltage AR2 of the stealth mode.

For the normal mode, a maximum threshold voltage in the first distribution Er1 (a voltage corresponding to a tail on a high voltage side in the distribution) is lower than a predetermined voltage. A minimum threshold voltage in the second distribution A2 (a voltage corresponding to a tail on a low voltage side in the distribution) is higher than the predetermined voltage, and a maximum threshold voltage in the second distribution A2 is lower than the voltage Vread. For example, the predetermined voltage is 0 V. The read voltage AR1 in the normal mode is set to a substantially intermediate voltage between the maximum threshold voltage in the first distribution Er1 and the minimum threshold voltage in the second distribution A2. The verify voltage AV1 in the normal mode is set to a voltage between the read voltage AR1 and the minimum threshold voltage in the second distribution A2. The verify voltage AV2 in the stealth mode is set to a voltage between the read voltage AR2 and a minimum threshold voltage in the fourth distribution A4.

The third distribution Er3 in the stealth mode is shifted to a high voltage side compared to the first distribution Er1 in the normal mode. As a result, at least a part of the third distribution Er3 in the stealth mode exists between the maximum threshold voltage in the first distribution Er1 and the minimum threshold voltage in the second distribution A2 in the normal mode. In the stealth mode, a maximum threshold voltage in the third distribution Er3 is higher than the read voltage AR1 in the normal mode. That is, the read voltage AR1 in the normal mode overlaps the third distribution Er3. In the example of FIG. 7, the maximum threshold voltage in the third distribution Er3 is located on a higher voltage side than the minimum threshold voltage in the second distribution A2 in the normal mode. That is, the second distribution A2 and the third distribution Er3 overlap each other. The maximum threshold voltage in the third distribution Er3 in the stealth mode may be located on a lower voltage side than the minimum threshold voltage in the second distribution A2 in the normal mode.

On the other hand, while a position of a peak of the fourth distribution A4 in the stealth mode is at a higher voltage than a position of a peak of the second distribution A2 in the normal mode, a maximum threshold voltage in the fourth distribution A4 in the stealth mode is lower than the voltage Vread similarly to the maximum threshold voltage in the second distribution A2 in the normal mode. In the example of FIG. 7, the maximum threshold voltage in the fourth distribution A4 is at substantially the same position as the maximum threshold voltage in the second distribution A2. The maximum threshold voltage in the fourth distribution A4 may be a lower voltage or may be a higher voltage than the maximum threshold voltage in the second distribution A2.

A width of each of the third distribution Er3 and the fourth distribution A4 in the stealth mode is smaller than a width of each of the first distribution Er1 and the second distribution A2 in the normal mode. The read voltage AR2 in the stealth mode is set to a voltage that is higher than the read voltage AR1 in the normal mode and is a substantially intermediate voltage between the maximum threshold voltage in the third distribution Er3 and the minimum threshold voltage in the fourth distribution A4.

In FIG. 7, since the maximum threshold voltage in the second distribution A2 and the maximum threshold voltage in the fourth distribution A4 are substantially the same voltage, the common voltage Vread can be used in the read operation for the first memory cell for which the write operation in the normal mode is executed and the read operation for the second memory cell for which the write operation in the stealth mode is executed. The voltage Vread is higher than any of the read voltage AR1 in the normal mode and the read voltage AR2 in the stealth mode. The maximum threshold voltage in the second distribution A2 in the normal mode and the maximum threshold voltage in the fourth distribution A4 in the stealth mode are both lower than the voltage Vread, and thus, the erase operation can be executed collectively for the memory cell for which the write operation in the normal mode is executed and the memory cell for which the write operation in the stealth mode is executed.

When the erase operation is executed collectively as described above, the threshold voltage distribution of the memory cell in the initial state is the first distribution Er1 regardless of the mode. Therefore, in a normal mode, when the threshold voltage of the memory cell is controlled to the first distribution Er1, the program operation is not executed for the memory cell, and in a stealth mode, when the threshold voltage of the memory cell is controlled to the third distribution Er3, the program operation is executed for the memory cell. In any case of the normal mode and the stealth mode, when the threshold voltage of the memory cell is to be controlled to the second distribution A2 or the fourth distribution A4, the program operation is executed for the memory cell.

The write operation in the normal mode may be referred to as a "first write operation". The write operation in the stealth mode may be referred to as a "second write operation". The read operation in the normal mode may be referred to as a "first read operation". The read operation in the stealth mode may be referred to as a "second read operation". The memory controller 2 executes a first write operation, a second write operation, a first read operation, and a second read operation in response to a first write instruction, a second write instruction, a first read instruction, and a second read instruction from an external memory controller, respectively. The read voltage AR1 in the normal mode may be referred to as a "first voltage". The read voltage AR2 in the stealth mode may be referred to as a "second voltage".

In the semiconductor memory device according to the present embodiment, information for specifying an address of a memory cell (or a page or a block) for which a write operation is performed in a stealth mode is stored in the register 26. When the semiconductor memory device executes a read operation, it is determined whether the memory cell, which is a target of the read operation, is written in a stealth mode, on the basis of an address of the memory cell. When determination is made that write is performed for the memory cell in the stealth mode, the read operation in the stealth mode is executed for the memory cell. On the other hand, when determination is made that write is performed for the memory cell in the normal mode, the read operation in the normal mode is executed for the memory cell.

In the above-described example, although a configuration in which information for specifying the address of the memory cell for which the write operation is performed in the stealth mode is stored in the register 26 is shown, information for specifying the address of the memory cell for which the write operation is performed in the normal mode may be stored in the register 26 in addition to the information or instead of the information.

As described above, since the maximum threshold voltage in the third distribution Er3 in the stealth mode is greater than the read voltage AR1 in the normal mode, when the read operation is executed using the read voltage AR1 in the normal mode for the memory cell into which the third distribution Er3 is written in the stealth mode, determination may be made that the memory cell is at the "A" level. That is, when the read operation is performed in the normal mode for the memory cell for which the write operation is performed in the stealth mode, it is not possible to determine correct data.

Accordingly, when it is not ascertained whether the write operation in the normal mode or the write operation in the stealth mode is performed for the memory cell, it is not possible to correctly determine the write level of the memory cell. In particular, when the maximum threshold voltage in the third distribution Er3 in the stealth mode is located on a higher voltage side than the minimum threshold voltage in the second distribution A2 in the normal mode, the third distribution Er3 and the second distribution A2 overlap each other. For this reason, it is substantially not possible to determine data stored in the memory cell.

In the semiconductor memory device, the write level of the memory cell may be measured by supplying a voltage and a signal from the outside using a probe. When this method is used, there is a risk that information stored in the semiconductor memory device will be stolen by a malicious third party.

It should be noted that the third party who does not know a memory cell into which data is written in the stealth mode is supposed to determine the write level of data for all memory cells on the basis of the same determination criterion. Accordingly, when the write operation is performed in the stealth mode for some memory cells provided in the semiconductor memory device, the third party cannot acquire correct information. For this reason, it is possible to reduce the risk that information stored in the semiconductor memory device is stolen. That is, it is possible to increase the security of data stored in the semiconductor memory device.

In FIG. 7, the SLC type is described. For this reason, while a configuration in which each of the first distribution Er1 and the third distribution Er3 corresponds to the erased state of the memory cell was described as an example, but the present disclosure is not limited to this configuration. For example, the first distribution and the third distribution may correspond to the distribution of the "F" level in FIG. 6, and the second distribution and the fourth distribution may correspond to the distribution of the "G" level.

### 2. Second Embodiment

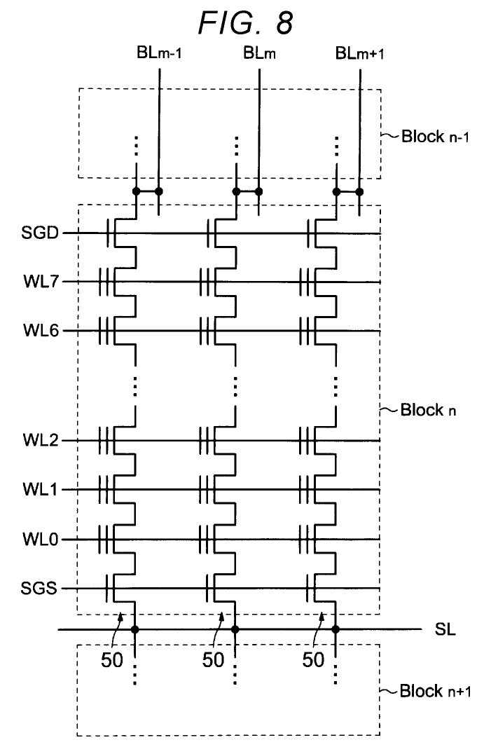

A semiconductor memory device according to a second embodiment will be described with reference to FIGS. 8 to 10. The second embodiment is one of application examples of the semiconductor memory device according to the first embodiment. Since a configuration and a read operation of a memory system according to the second embodiment are similar to those of the memory system according to the first embodiment, the memory system according to the second embodiment will be described with reference to FIGS. 1 to 7. In the description of the present embodiment, configurations and operations similar to those of the first embodiment will not be repeated.

FIGS. 8 to 10 are diagrams showing a circuit configuration of a block in the semiconductor memory device according to the embodiment. In these drawings, while a specific circuit configuration is shown for "Block n", "Block n-1" and "Block n+1" also have a similar circuit configuration to "Block n".

As shown in FIG. 8, a string 50 is provided between each of bit lines BLm-1, BLm, and BLm+1 and the source line SL. Since the configuration of each string 50 is as described with reference to FIG. 5, detailed description thereof will not be repeated. In the present embodiment, one page is configured with memory cells connected to the same word line WL in the same block. In the present embodiment, a configuration in which the normal mode and the stealth mode are divided in units of a plurality of memory cells connected to the same word line WL in the same string 50 is described as an example.

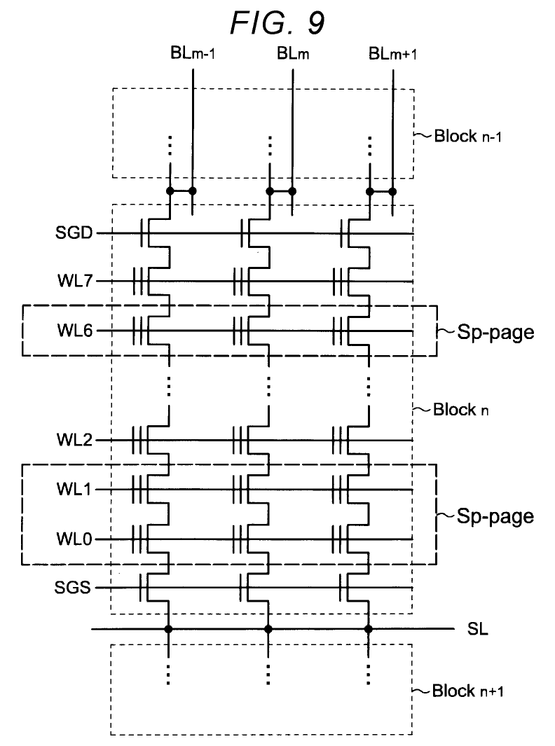

An example shown in FIG. 9 shows a configuration in which the normal mode and the stealth mode are mixed in one block "Block n". Specifically, in the memory cells connected to the word lines WL0, WL1, and WL6, the write operation and the read operation in the stealth mode are executed. In the memory cells connected to other word lines WL, the write operation and the read operation in the normal mode are executed. A page corresponding to the stealth mode is referred to as a stealth page (SP-page). As described above, even in the memory cells connected to the same bit line BL, the write operation and the read operation in the normal mode are executed for one memory cell, and the write operation and the read operation in the stealth mode are executed for the other memory cell.

In the above-described case, information indicating that the pages corresponding to the word lines WL0, WL1, and WL6 are stealth pages in "Block n" is stored in the register 26. When the write command or the read command is received from the external host computer, the memory controller 2 determines whether the memory cell corresponding to the command is included in the stealth page. When determination is made that the target memory cell is included in the stealth page, the memory controller 2 executes the write operation or the read operation in the stealth mode for the memory cell.

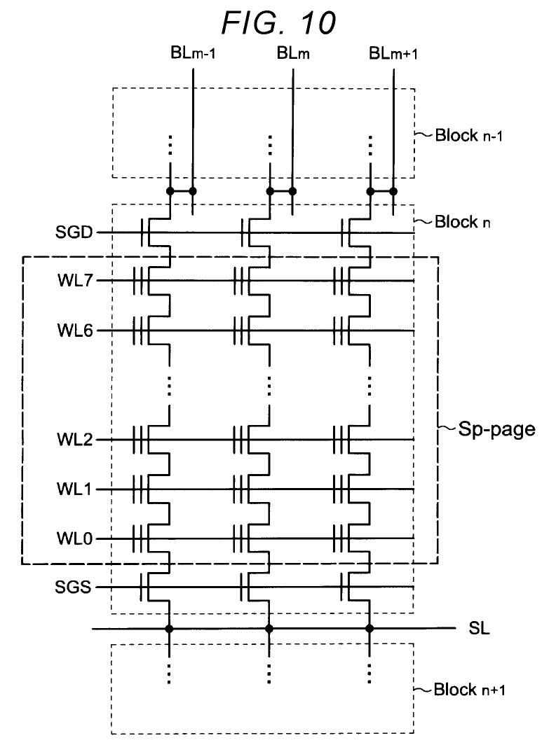

An example shown in FIG. 10 shows a configuration in which all memory cells in one block "Block n" are in the stealth mode. That is, the write operation and the read operation in the stealth mode are executed for the memory cells connected to the word lines WL0 to 7. In this case, "Block n" can be referred to as a stealth block.

As described above, even in the semiconductor memory device according to the second embodiment, it is possible to obtain similar effects to the first embodiment.

### 3. Modification Example

In the present embodiment, although the SLC type was described, the above-described technical idea may be applied to the MLC type, the TLC type, the QLC type, the PLC type, or the HLC type. In this case, the normal mode and the stealth mode described above may be applied to all write levels in each type or the normal mode and the stealth mode described above may be applied to some write levels.

The memory controller 2 may execute the write operation (first write operation) in the normal mode or the write operation (second write operation) in the stealth mode on the basis of the write command received from the external host computer. For example, the memory controller 2 may execute the first write operation on the basis of a first write command and execute the second write operation on the basis of a second write command. Similarly, the memory controller 2 may execute the read operation (first read operation) in the normal mode or the read operation (second read operation) in the stealth mode on the basis of the read command received from the external host computer. For example, the memory controller 2 may execute the first read operation on the basis of a first read command and execute the second read operation on the basis of a second read command.

When the memory controller 2 executes the first write operation or the second write operation on the basis of the command as described above, the memory controller 2 may determine a memory cell (first memory cell) for which the first write operation is executed and a memory cell (second memory cell) for which the second write operation is executed, on the basis of the command. That is, when the first write operation is executed for the first memory cell on the basis of the above-described first write command, the first read operation is executed for the first memory cell on the basis of the first read command corresponding to the first write operation command. Similarly, when the second write operation is executed for the second memory cell on the basis of the second write command, the second read operation is executed for the second memory cell on the basis of the second read command.

The write command issued from the external host computer may include flag information indicating that data with high confidentiality is included in data stored in the semiconductor memory device. In this case, when detection is made that the write command received from the external host computer includes the flag information, the memory controller 2 may execute the write operation in the stealth mode for data (data with high confidentiality) specified by the flag information.

In this case, among data stored in the semiconductor memory device on the basis of the above-described write command, only data specified by the flag information may be written by the write operation in the stealth mode, and the rest of data may be written by the write operation in the normal mode. Alternatively, all data stored in the semiconductor memory device on the basis of the write command including the flag information may be written by the write operation in the stealth mode. Information for specifying an address of a memory cell into which data is written by the write operation in the stealth mode is stored in the register 26. When the semiconductor memory device executes the read operation, determination of whether a memory cell to be read is written in the stealth mode is performed on the basis of an address of the memory cell to be read, and the read operation based on the determination result is executed.

The write operation in the stealth mode may be executed on the basis of specific conditions or randomly even when the stealth page SP-page or the stealth block is not set in advance as in the second embodiment or the flag information is not included in the write command issued from the host computer. Even in this case, information for specifying the address of the memory cell into which data is written by the write operation in the stealth mode is stored in the register 26.

Although the present disclosure was described above with reference to the drawings, the present disclosure is ot limited to the above-described embodiments, and can be modified as appropriate without departing from the spirit of the present disclosure. For example, additions, deletions, or design changes of components made by those skilled in the art based on the semiconductor memory device of the present embodiment are also included in the scope of the present disclosure as long as the gist of the present disclosure is provided. In addition, the above-described embodiments can be combined as appropriate as long as there are no contradictions, and technical matters common to each embodiment are included in each embodiment unless otherwise explicitly stated.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a control circuit;
a first word line; and
a memory array including a first memory cell connected to the first word line and configured to store n bits (where n is an integer equal to or greater than one),
wherein the control circuit is configured to
execute a first write operation in response to a first write instruction from an external memory controller, execute a second write operation in response to a second write instruction from the external memory controller, execute a first read operation in response to a first read instruction from the external memory controller, and execute a second read operation in response to a second read instruction from the external memory controller,
control, by executing the first write operation, a threshold voltage of the first memory cell to fall within any of 2ⁿ distributions including a first distribution and a second distribution arranged in an order of increasing voltage,
determine, by executing the first read operation, whether the threshold voltage of the first memory cell falls within the first distribution or the second distribution, on the basis of a first voltage,
control, by executing the second write operation, the threshold voltage of the first memory cell to fall within any of 2ⁿ distributions including a third distribution and a fourth distribution arranged in an order of increasing voltage, and
determine, by executing the second read operation, whether the threshold voltage of the first memory cell falls within the third distribution or the fourth distribution, on the basis of a second voltage higher than the first voltage, and
at least a part of the third distribution exists between the first distribution and the second distribution.

2. The semiconductor memory device according to claim 1,
wherein the first voltage overlaps the third distribution.

3. The semiconductor memory device according to claim 1,
wherein a width of the fourth distribution is smaller than a width of the second distribution.

4. The semiconductor memory device according to claim 3,
wherein a width of the third distribution is smaller than a width of the first distribution.

5. The semiconductor memory device according to claim 1, further comprising:
a second word line,
wherein the memory array includes a second memory cell connected to the second word line and configured to store n bits,
the control circuit is configured to
execute the first write operation for the first memory cell in response to the first write instruction,
execute the second write operation for the second memory cell in response to the second write instruction,
execute the first read operation for the first memory cell by supplying a third voltage to the first word line in response to the first read instruction, and
execute the second read operation for the second memory cell by supplying the third voltage to the second word line in response to the second read instruction, and
the third voltage is higher than the first voltage and the second voltage.

6. The semiconductor memory device according to claim 5, further comprising:
a bit line and a source line,
wherein the first memory cell and the second memory cell are connected in series between the bit line and the source line.

7. The semiconductor memory device according to claim 1, further comprising:
a second word line,
wherein the memory array includes a second memory cell connected to the second word line and configured to store n bits,
the first write operation includes a first program operation to increase the threshold voltage of the first memory cell and a first verify operation to verify the threshold voltage of the first memory cell after the first program operation,
the second write operation includes a second program operation to increase a threshold voltage of the second memory cell and a second verify operation to verify the threshold voltage of the second memory cell after the second program operation,
the control circuit is configured to
repeat the first program operation and the first verify operation until the threshold voltage of the first memory cell reaches a first verify voltage being used in the first verify operation, and
repeat the second program operation and the second verify operation until the threshold voltage of the second memory cell reaches a second verify voltage being used in the second verify operation, and
the second verify voltage is higher than the first verify voltage.

8. The semiconductor memory device according to claim 1,
wherein the first distribution is a distribution corresponding to an erased state of the first memory cell.

9. The semiconductor memory device according to claim 8,
wherein the control circuit is configured to execute a program operation in controlling the threshold voltage of the first memory cell to fall within the third distribution.

10. The semiconductor memory device according to claim 9,
wherein the control circuit is configured to not execute the program operation to increase the threshold voltage of the first memory cell.

11. The semiconductor memory device according to claim 1,
wherein the control circuit is configured to execute the first write operation on the basis of a first write command received from an external host computer, execute the second write operation on the basis of a second write command, execute the first read operation on the basis of a first read command, and execute the second read operation on the basis of a second read command.

12. The semiconductor memory device according to claim 11, further comprising:
a second word line,
wherein the memory array includes a second memory cell connected to the second word line and configured to store n bits, and
the control circuit is configured to
execute the first write operation for the first memory cell on the basis of the first write command and execute the first read operation for the first memory cell on the basis of the first read command, and
execute the second write operation for the second memory cell on the basis of the second write command and execute the second read operation for the second memory cell on the basis of the second read command.

13. The semiconductor memory device according to claim 1,
wherein the control circuit is configured to
determine that flag information is included in a command received from an external host computer, and execute the second write operation and the second read operation, and
determine that the flag information is not included in a command from the external host computer, and execute the first write operation and the first read operation.

14. A semiconductor memory device comprising:
a control circuit; and
a memory array including a first memory cell,
wherein the control circuit is configured to
control, by executing a first write operation, a threshold voltage of the first memory cell to fall within one of a first distribution and a second distribution arranged in an order of increasing voltage,
determine, by executing a first read operation, whether the threshold voltage of the first memory cell falls within the first distribution or the second distribution, on the basis of a first voltage,
control, by executing a second write operation, the threshold voltage of the first memory cell to fall within one of a third distribution and a fourth distribution arranged in an order of increasing voltage, and
determine, by executing a second read operation, whether the threshold voltage of the first memory cell falls within the third distribution or the fourth distribution, on the basis of a second voltage higher than the first voltage, and
at least a part of the third distribution exists between the first distribution and the second distribution.

15. The semiconductor memory device according to claim 14,
wherein the first voltage overlaps the third distribution.

16. The semiconductor memory device according to claim 14,
wherein a width of the fourth distribution is smaller than a width of the second distribution.

17. The semiconductor memory device according to claim 16,
wherein a width of the third distribution is smaller than a width of the first distribution.

18. The semiconductor memory device according to claim 14, wherein the control circuit is further configured to:
execute the first write operation in response to a first write instruction from an external memory controller;
execute the second write operation in response to a second write instruction from the external memory controller;
execute the first read operation in response to a first read instruction from the external memory controller; and
execute the second read operation in response to a second read instruction from the external memory controller.

19. The semiconductor memory device according to claim 18, further comprising:
a first word line connected to the first memory cell; and
a second word line,
wherein the memory array includes a second memory cell connected to the second word line,
the control circuit is configured to
execute the first write operation for the first memory cell in response to the first write instruction,
execute the second write operation for the second memory cell in response to the second write instruction,
execute the first read operation for the first memory cell by supplying a third voltage to the first word line in response to the first read instruction, and
execute the second read operation for the second memory cell by supplying the third voltage to the second word line in response to the second read instruction, and
the third voltage is higher than the first voltage and the second voltage.

20. The semiconductor memory device according to claim 14,
wherein the first distribution is a distribution corresponding to an erased state of the first memory cell.
